(19) United States
(12) Patent Application Publication
(10) Pub. No.: US 2011/0147701 A1
(43) Pub. Date: Jun. 23, 2011

(54) IMAGE DISPLAY DEVICE

(75) Inventor: Kiyokatsu Ikemoto, Yokohama-shi (JP)

(73) Assignee: CANON KABUSHIKI KAISHA, Tokyo (JP)

(21) Appl. No.: 12/963,830

(22) Filed: Dec. 9, 2010

(30) Foreign Application Priority Data
Dec. 17, 2009 (JP) 2009-286478

(51) Int. Cl. H01L 33/04

(52) U.S. Cl. 257/13; 257/E33.005

(57) ABSTRACT

An image display device includes a display surface constituted of a plurality of pixels, each of the pixels having a light-emitting layer, a front panel arranged at the ambient light entering side relative to the light-emitting layer, and a structure layer arranged between the light-emitting layer and the front panel. The structure layer has a structure containing particles arranged in a surrounding region and showing a refractive index distribution in a plane parallel to the display surface, each of the particles being constituted of a core and a shell forming an outer peripheral region relative to the core. The core, the shell, and the front panel and/or the surrounding region have different respective refractive indexes satisfying the requirement of N_{core} (refractive index of core)>Nₛₕₑₗₗ (refractive index of shell)>N_{low} (refractive index of front panel or surrounding region whichever lower).

### BACKGROUND OF THE INVENTION

1. Field of the Invention

The present invention relates to an image display device. More particularly, the present invention relates to an image display device capable of displaying images of high contrast.

2. Description of the Related Art

Image display devices that are devised in various different ways have been proposed. As an example, an image display device having an arrangement as illustrated in cross section in FIG. 6 is known. FIG. 6 shows a single pixel 1002. An image display device 1000 is formed by arranging a plurality of such pixels. The image display device 1000 shown in FIG. 6 has a light-emitting section arranged on the inner surface of a front panel 1001. The front panel 1001 is formed by means of a medium that is transparent relative to visible light such as glass or plastic. The light-emitting section includes a light-emitting layer 1003 and an excitation source 1004 for exciting the light-emitting layer. The excitation source 1004 is typically formed by arranging an electron-emitting element (cathode) and an opposite electrode (anode) respectively on a substrate and between the front panel 1001 and the light-emitting layer 1003. With the above-described arrangement, electrons are emitted as an electric field is applied between the electron-emitting element and the opposite electrode and the light-emitting layer emits light as the emitted electrons are fed to the light-emitting layer. The excitation source 1004 may alternatively be formed by arranging an anode and a cathode respectively on the front surface and on the rear surface of the light-emitting layer. Light emitted from the light-emitting layer then passes through the front panel 1001 and drawn to the outside to operate as display light 1005.

Image display devices are required to display images of high contrast. The display brightness needs to be raised and reflected ambient light needs to be reduced in a light environment in order to improve the contrast of the image being displayed by an image display device, whereas the minimum brightness needs to be reduced if the image being displayed involves black. As used herein, the expression of reflected ambient light refers to ambient light that enters an image display device and is then reflected in the device and drawn to the outside. As ambient light 1006 enters the image display device 1000, the light 1006 is reflected at the interface of the front panel 1001 and the light-emitting layer 1003 and by the rear surface of the light-emitting layer 1003 and that of the excitation source 1004 to produce intense reflected light, which is shown as reflected light 1007 in FIG. 6. Additionally, to raise the brightness of display light of the image display device 1000, it is important to reduce the loss of light that takes place between when light is emitted from the light-emitting layer 1003 and when the light is drawn to the outside. The factors that give rise to such a loss include the total reflection loss at the interface of the light-emitting layer 1003 and the front panel 1001 and also at the interface of the front panel 1001 and the external region. When light propagates from a high refractive index medium toward a low refractive index medium, light that propagates at an angle greater than the critical angle is totally reflected and confined in the high refractive index medium. Such light is not drawn into the low refractive index medium but propagates in the high refractive index medium to give rise to a loss of light.

Techniques have been proposed to reduce the total reflection loss and raise the brightness of display light by arranging a micro-structure between layers formed by means of respective mediums having refractive indexes that are different from each other. For example, Japanese Patent Application Laid-Open No. 2008-243669 describes an arrangement illustrated in FIG. 7. FIG. 7 illustrates an image display device 1100 including a front panel 1101, a transparent electrode 1102, a light-emitting layer 1103 and an electrode layer 1104, and provided with a micro-structure 1105 being arranged between the front panel 1101 and the light-emitting layer 1103. The micro-structure 1105 is a structure formed by arranging particles 1106 in a surrounding region 1107 and has a refractive index distribution of a cycle period of about the wavelength of light. It is known that light propagating at an angle not greater than the critical angle and display light 1108 drawn to the outside can be is amplified by diffracting light that is generated in the inside of the light-emitting layer 1103.

### SUMMARY OF THE INVENTION

The prior art technique described in Japanese Patent Application Laid-Open No. 2008-243669 has a problem of intense reflected ambient light 1112. This problem will be discussed below. Referring to FIG. 7, the medium that constitutes the particles 1106 has a refractive index different from that of the medium of the surrounding region 1107. As ambient light 1109 enters such a micro-structure 1105, the light 1109 is reflected at the interfaces 20 of the particles 1106 and the surrounding region 1107 and at the interfaces 21 of the front panel 1101 and the particles 1106 due to the difference of refractive index. The reflected light becomes reflected-and-diffracted light, some of which propagates at an angle within the critical angle, is emitted outside the front panel and becomes reflected ambient light 1112. With such a known arrangement, intense reflected light is produced at the interfaces 20 and also at the interfaces 21 because of a large difference of refractive index observed there. Then, the quantity of the reflected ambient light 1112 is raised by such reflected light to operate as a factor of reduction of contrast. For this reason, in the prior art, an additional unit is provided to reduce reflected ambient light. The additional unit may be a light absorbing filter or a combination of an absorption type polarization filter and a quarter-wave plate. However, display light 1108 is also absorbed when such a unit is employed to by turn reduce the display brightness and increase the power consumption rate.

In view of the above-identified problem, it is therefore the object of the present invention to provide an image display device that can reduce reflected ambient light and raise the brightness of display light and is capable of displaying images of high contrast.

According to the present invention, the above identified problem is dissolved by providing an image display device including a display surface constituted of a plurality of pixels; each of the pixels having a light-emitting layer, a front panel arranged at the ambient light entering side relative to the light-emitting layer and a structure layer arranged between the light-emitting layer and the front panel; the structure layer having a structure containing particles arranged in a surrounding region and showing a refractive index distribution in a plane parallel to the display surface; each of the particles being constituted of a core and a shell forming an outer peripheral region relative to the core; the core, the shell, and the front panel and/or the surrounding region being formed by media having different respective refractive indexes; the refractive indexes satisfying the requirement of formula 1 shown below:

N_{core}>Nₛₕₑₗₗ>N_{low} (formula 1),

where Nₒ, represents the refractive index of the medium of the core; Nₛₕₑₗₗ represents the refractive index of the medium of the shell; and N_{low} represents the refractive index of the front panel or that of the surrounding region, whichever lower than the other.

Thus, according to the present invention, it is possible to reduce reflected ambient light and, at the same time, raise the brightness of display light. Thus, it is possible to provide an image display device capable of displaying images of high contrast.

Further features of the present invention will become apparent from the following description of exemplary embodiments with reference to the attached drawings.

### BRIEF DESCRIPTION OF THE DRAWINGS

FIGS. 1A and 1B are a schematic illustration of the configuration of the image display device of Embodiment of the present invention. FIG. 1A is an xz cross sectional view of the image display device and FIG. 1B is an xy cross sectional view of the micro-structure of the image display device.

FIG. 2 is a graph illustrating the ambient light reflectance obtained as a result of computations done for Embodiment 1 of the present invention.

FIG. 3 is a graph illustrating the ambient light reflectance obtained as a result of computations done for Embodiment 1 of the present invention.

FIG. 4 is a graph illustrating the ambient light reflectance and light extraction efficiency obtained as a result of computations done for Embodiment 1 of the present invention.

FIG. 5 is an xz cross sectional view of the image display device of Embodiment 2 of the present invention.

FIG. 6 is an xz cross sectional view of a prior art image display device.

FIG. 7 is an xz cross sectional view of a prior art image display device disclosed in Japanese Patent Application Laid-Open No. 2008-243669.

### DESCRIPTION OF THE EMBODIMENTS

Now, the present invention will be described in greater detail by referring to the accompanying drawings that illustrate preferred embodiments of the invention.

### EMBODIMENTS

### Embodiment 1

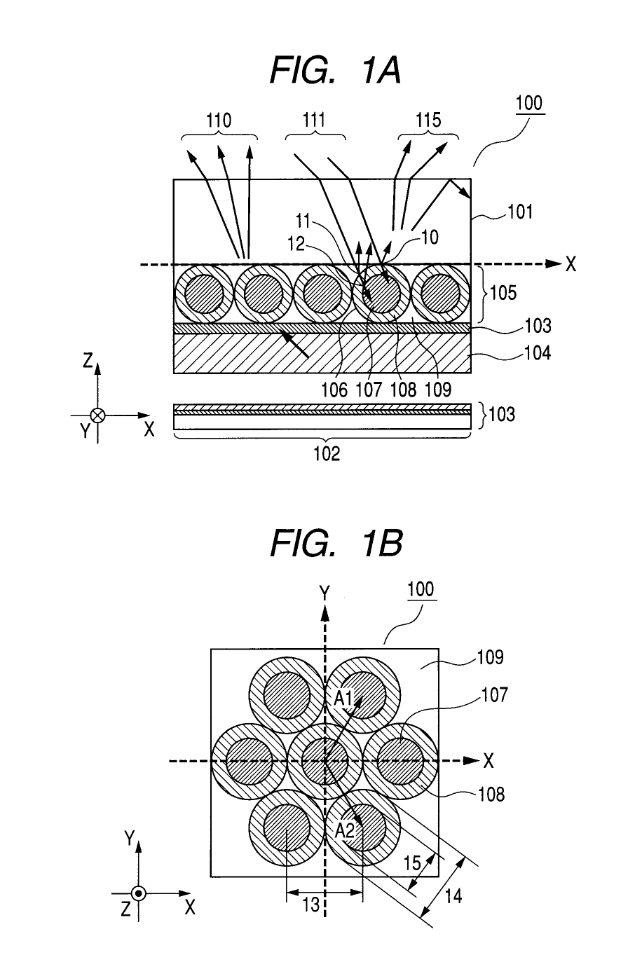

Firstly, Embodiment 1 of image display device according to the present invention will be described below by referring to FIGS. 1A and 1B. FIG. 1A shows an xz cross sectional view of the image display device, which is generally denoted by 100. The image display device 100 of this embodiment includes a front panel 101 and a light-emitting section, which is arranged on the rear surface of the front panel 101. FIGS. 1A and 1B show a single pixel 102. The image display device 100 is formed by arranging a plurality of such pixels 102. Individual pixels 102 are partitioned by a black matrix that is formed by a light-absorbing medium. The front panel 101 is formed by means of a medium that is transparent relative to visible light and may typically be glass.

The light-emitting section includes a light-emitting layer 104, a structure layer 105 and an excitation source (excitation unit) 103. The structure layer 105 is arranged between the light-emitting layer 104 and the front panel 101 and arranged at the side close to the ambient light entering side of the device relative to the light-emitting layer. The light-emitting layer 104 is typically formed by a film that contains a fluorescent material and generates light within a wavelength zone between 350 nm and 800 nm, which corresponds to the wavelength zone of visible light. The structure layer 105 has a structure formed by arranging particles 106 in xy plane that is parallel to the display surface. The particles 106 are formed by means of mediums, the medium of the central area of each particle differing from the medium of the peripheral area of the particle. The central area of the particle 106 is referred to as core, whereas the peripheral area of the particle 106 is referred to as shell. The structure layer 105 has a structure in which the particles 106, each of which includes a core 107 and a shell 108 formed in the outer peripheral region of the core, are surrounded by a surrounding region 109. The cores 107, the shells 108 and the surrounding region 109 are made of respective mediums having refractive indexes that are different from each other.

FIG. 1B is an yz cross sectional view of the structure layer 105, showing an exemplar configuration thereof. The structure layer 105 has a triangular lattice structure, in which particles 106 are arranged at respective positions, each of which is expressed by the sum or the difference of two basic lattice vectors, or basic lattice vector A1 and basic lattice vector A2, as shown in FIG. 1B. If the length of the lattice period 13 is a, the vector A1 is a vector of (0.5a, √3a/2, 0.0) and the vector A2 is a vector of (0.5a, −√3a/2, 0.0). The excitation source 103 includes a unit for injecting electrons into the light-emitting layer 104. For example, the excitation source 103 may be formed by arranging electron-emitting elements and an electrode on a substrate and additionally arranging a transparent electrode on the surface of the light-emitting layer 104. With the above-described arrangement, as an electric field is applied to the electron-emitting elements, electrons are emitted toward and supplied to the light-emitting layer 104 to generate light. Light that is generated in this way is then transmitted through the structure layer 105 and the front panel 101 and drawn to the outside to operate as display light 110 that propagates in the +z direction.

Now, the reason why the image display device 100 according to the present invention can display images of high contrast will be described below. Referring to FIG. 1A, as ambient light 111 enters the image display device 100, the light 111 is transmitted through the interface of the external region and the front panel 101 and gets to the structure layer 105. Light that gets to the structure layer 105 gives rise to rays of reflected light at the interfaces 10 of the front panel 101 and the shells 108, at the interfaces 11 of the shells 108 and the surrounding region 109 and also at the interfaces 12 of the cores 107 and the shells 108 due to the difference of refractive index. The rays of reflected light that are produced at the interfaces then become rays of reflected-and-diffracted light and the rays of reflected-and-diffracted light propagating at an angle not greater than the critical angle of the interface of the front panel and the external region are accumulated to produce rays of reflected ambient light 115. The medium of the cores 107, that of the shells 108 and that of the surrounding region 109 are selected so as to satisfy the requirement of formula (I) shown below:

N_{core}>Nₛₕₑₗₗ>N_{low} (formula 1),

Where N_{core}: the refractive index of the medium of the cores 107;
Nₛₕₑₗₗ: the refractive index of the medium of the shells 108; and
N_{low}: the refractive index of the front panel 101 or that of the surrounding region 109, whichever lower than the other. With the above-described arrangement, the difference of refractive index at each interface can be minimized to reduce the intensity of reflected light that is produced at each interface and hence the reflected ambient light 115. Particles 106, each being formed by means of a core 107 and a shell 108, are arranged in the surrounding region 109 and the medium of the shells 108 is appropriately selected. Then, as a result, it is possible to reduce reflected light at the interfaces of the particles 106 and the front panel 101 and at the interfaces of the particles 106 and the surrounding region 109 to by turn reduce the reflected ambient light 115.

The structure layer 105 diffracts light generated in the inside of the light-emitting layer 104, amplifies light propagating at an angle not greater than the critical angle of the interface of the light-emitting layer 104 and the front panel 101 and that of the interface of the front panel 101 and the outside and improves the brightness of display light 110. Thus, the image display device 100 capable of displaying images of high contrast can be realized by appropriately defining the structure and selecting the medium of the structure layer 105 so as to reduce the reflected ambient light 115 and, at the same time, raise the brightness of display light 110. For this embodiment, it is possible to prepare a structure that contains particles 106 by firstly preparing particles 106, subsequently dispersing the particles 106 into a solvent, then applying the solution to the front panel 101 and ultimately removing the solvent. Thus, a closed-packed structure in which particles 106 are distributed in a triangular lattice pattern and the particles 106 are distributed in a triangular lattice pattern and the particles 106 that are arranged closest to each other are held in contact with each other can be prepared with ease by appropriately defining the conditions of each step of preparing the structure. A structure layer 105 having a particle diameter 14 and a core diameter 15 and periodic arrangement intervals 13 that are optimal can be prepared by way of a simple process of preparing particles 106 having an appropriate diameter 14 and an appropriate core diameter 15 in advance and arranging them appropriately.

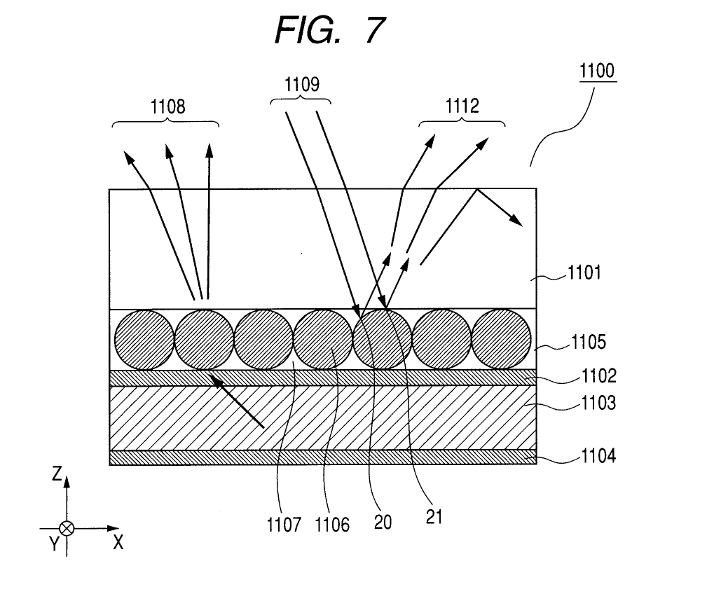

With the prior art arrangement illustrated in FIG. 7, the diameter of the particles 1106 and each of the periodic arrangement intervals are equal to each other and reflected ambient light is intense in a structure obtained by way of the above-described steps. A micro-structure in which the diameter of the particles 1106 and each of the periodic arrangement intervals differ from each other may be conceivable for a prior art arrangement. However, preparing such a structure requires an additional process of reducing the external size of each of the particles by etching, for example, after arranging the particles in position to increase the number of manufacturing steps. On the other hand, with this embodiment, a micro-structure having an optimal structure can be obtained by way of a simple process. Thus, an image display device capable of displaying images of high contrast can be obtained due to the effect of reducing reflected ambient light and that of raising the brightness of display light.

Now, an example of structure layer 105 that is contained in the image display device 100 of this embodiment will be described below. Referring to FIGS. 1A and 1B, the structure layer 105 has a lattice period 13 of 2,300 nm, a particle diameter 14 of 2,300 nm and a core diameter 15 of 1,150 nm. The refractive index of the medium of the cores of the particles 106 is 2.6 and the refractive index of the medium of the surrounding region 109 is 1.0. The front panel 101 is formed by means of a medium having a refractive index of 1.46 and the light-emitting layer 104 is formed by means of a medium having a refractive index of 1.5. A transparent electrode formed by means of a medium having a refractive index of 1.8 is arranged between the light-emitting layer 104 and the structure layer 105 as excitation source 103 and an electron source is arranged on the rear surface of the light-emitting layer 104. A region on the rear surface of the light-emitting layer 104 is void, or vacuum.

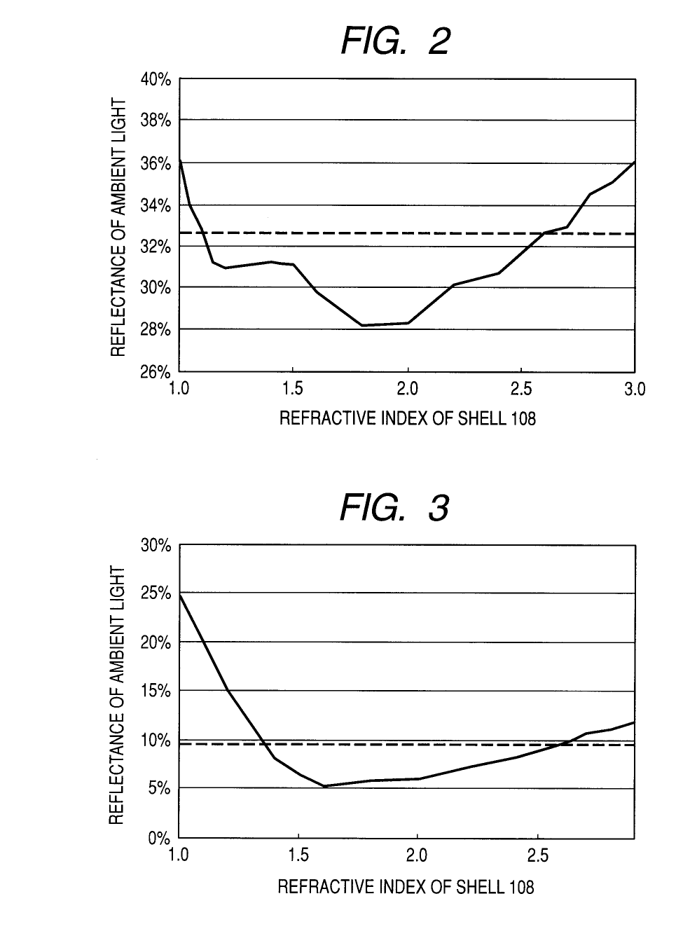

FIG. 2 illustrates the ambient light reflectance of when ambient light is entered for the image display device. In FIG. 2, the horizontal axis indicates the refractive index of the medium of the shell 108 and the vertical axis indicates the ambient light reflectance. In FIG. 2, the broken line shows the ambient light reflectance of a known image display device having a micro-structure. The micro-structure of the known device is same as the micro-structure 1105 shown in FIG. 7 and has a length of lattice period of 2,300 nm and a particle diameter of 2,300 nm. The refractive index of the medium of the particles 1106 is 2.6 whereas the refractive index of the medium of the surrounding region 1107, that of the medium of the front panel 1101, that of the medium of the light-emitting layer 1103 and that of the medium of the transparent electrode 1102 are same as those of this embodiment.

In FIG. 2, the broken line illustrates the characteristic of the known arrangement and the solid line illustrates the characteristic of the arrangement of the present invention. Note that reflected light at the interface of the front panel 101 and the external region and reflected light from the interface of the light-emitting layer 104 and the rear region do not show any difference between the present invention and the prior art and hence are disregarded. Although not shown, the ambient light reflectance of an actual image display device is reduced further to a low value by means of a black matrix and color filters. The ambient light reflectance is computed by means of the transfer matrix method. As shown in FIG. 2, with the arrangement of the present invention, the medium of the shell 108 shows a refractive index smaller than the medium of the core 107 and greater than the medium of the surrounding region 109. In other words, the ambient light reflectance can be reduced than ever by using a medium having a refractive index smaller than 2.6 and greater than 1.1. Then, as a result, it is possible to obtain an image display device having a low ambient light reflectance that is capable of displaying images of high contrast.

FIG. 3 is a graph illustrating the ambient light reflectance obtained as a result of computations done for Embodiment 1 of the present invention when the refractive index of the medium of the surrounding region 109 is 1.8. In FIG. 3, the horizontal axis indicates the refractive index of the medium of the shell 108 and the vertical axis indicates the ambient light reflectance. In FIG. 3, the broken line shows the ambient light reflectance of a prior art image display device having a micro-structure. In this embodiment, the lattice period 13 and the particle diameter 14 are same as those of FIG. 1B. The mediums of the front panel 101, the light-emitting layer 104, the transparent electrode 103 and the cores 107 are same as those of FIGS. 1A and 1B. Similarly, in the prior art image display device, the surrounding region 1107 of the micro-structure 1105 has a refractive index of 1.8 and the front panel 1101, the transparent electrode 1102, the light-emitting layer 1103, the particles 1106 and the surrounding region 1107 have respective refractive indexes that are same as those of this embodiment. Note that reflected light at the interface of the front panel 101 and the external region and reflected light from the interface of the light-emitting layer 104 and the rear region are disregarded. The ambient light reflectance is computed by means of the transfer matrix method. As shown in FIG. 3, the medium of the shell 108 shows a refractive index smaller than the medium of the core 107 and greater than the medium of the front panel 101. In other words, the ambient light reflectance can be reduced than ever by using a medium having a refractive index smaller than 2.6 and greater than 1.46. Then, as a result, it is possible to obtain an image display device having a low ambient light reflectance that is capable of displaying images of high contrast.

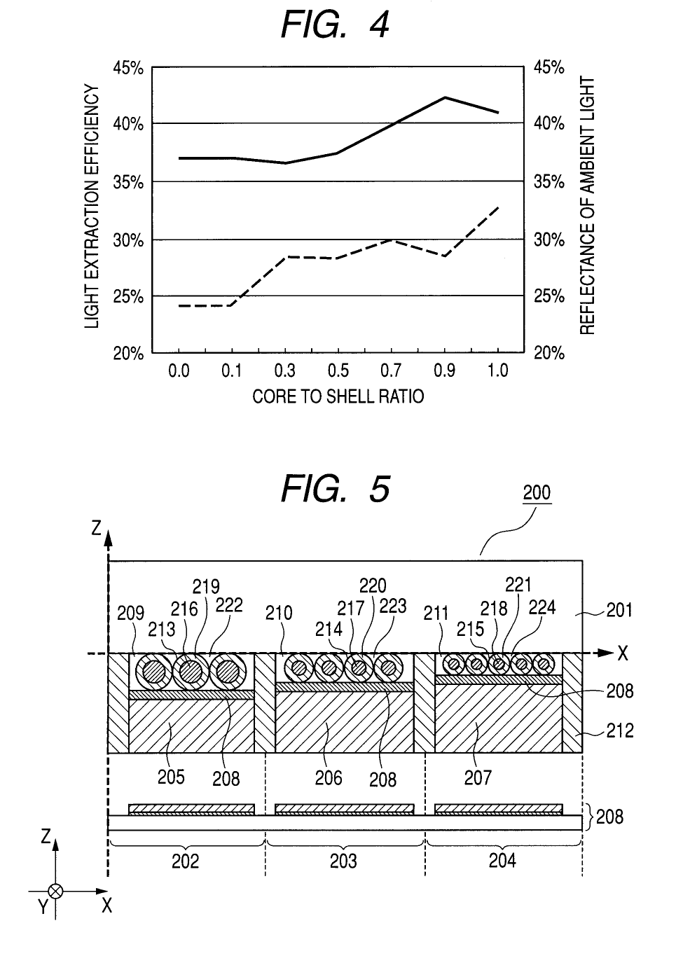

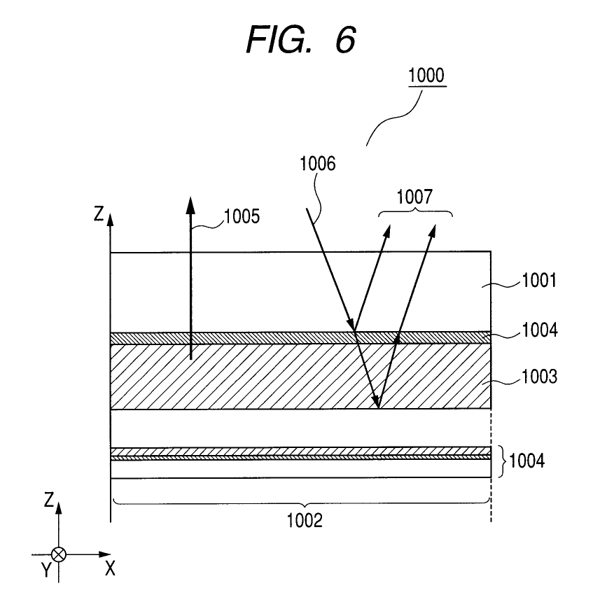

Additionally, in the macro-structure layer 105 of FIG. 1A, the quotient obtained by dividing the core diameter 15 by the particle diameter 14 is referred to as core to shell ratio hereinafter. FIG. 4 shows the ambient light reflectance that is obtained when the core to shell ratio is made to vary. The ratio of the quantity of light generated by the light-emitting layer to the quantity of light drawn to the outside as display light is referred to as light extraction efficiency hereinafter. FIG. 4 also shows the light extraction efficiency. In FIG. 4, the solid line indicates the light extraction efficiency and the broken line indicates the ambient light reflectance. In FIG. 4, the horizontal axis indicates the core to shell ratio and the left vertical axis indicates the light extraction efficiency while the right vertical axis indicates the ambient light reflectance. The lattice period 13, the particle diameter 14 and the mediums of the front panel 101, the light-emitting layer 104, the transparent electrode 103, the core 107 and the surrounding region 109 are same as those of FIGS. 1A and 1B. The refractive index of the medium of the shell 108 is 1.8.

As shown in FIG. 4, a high light extraction efficiency can be achieved to raise the brightness of display light by increasing the core to shell ratio of the particles. Additionally, the ambient light reflectance can be reduced by decreasing the core to ratio of the particles. For this embodiment, the core to shell ratio of the particles is preferably not smaller than 0.3 and not greater than 0.95. Both a remarkable effect of raising the brightness of display light and that of reducing the ambient light reflectance can be achieved by confining the ratio within the above range. More preferably, the core to shell ratio of the particles is not smaller than 0.5 and not greater than 0.9 to achieve more remarkable effects. In the image display device 100 of this embodiment, the structure layer 105 formed by means of particles 106, each having a core 107 and a shell 108, and a surrounding region 109 is arranged between the front panel 101 and the light-emitting layer 104. Then, mediums of the cores 107, the shells 108, the surrounding region 109 and the front panel 101 are appropriately selected so as to satisfy the requirement of the formula 1. As a result, it has been proved that the ambient light reflectance can be reduced.

When the lattice period that is the period of refractive index distribution in the structure layer 105 along a plane running in parallel with the display surface of the image display device is represented by Λ, the lattice period Λ preferably satisfies the requirement of the formula 2 shown below.

1.0 μm≦Λ≦3.0 μm (formula 2)

As ambient light 107 enters a structure having such a lattice period, the ambient light 107 is divided into reflected-and-diffracted light beams and transmitted-and-diffracted light beams. Then, reflected light beams are further divided into a number of reflected-and-diffracted light beams of the second and higher orders. Therefore, the intensity of each light beam shows a small value. Similarly, transmitted-and-diffracted light beams are further divided into a number of transmitted-and-diffracted light beams of the second and higher orders. Each transmitted-and-diffracted light beam is reflected by the rear surface of the light-emitting layer and subsequently enters the structure layer 105. Then, the transmitted-and-diffracted light beam is further divided into a number of transmitted-and-diffracted light beams and some of the transmitted-and-diffracted light beams turn out to be reflected ambient light beams. Since ambient light is divided into a number of transmitted-and-diffracted light beams before it is emitted to the outside, the intensity of each light beam shows a very small value. Thus, reflected ambient light is an accumulation of a large number of reflected-and-diffracted light beams and transmitted-and-diffracted light beams whose intensities are small. If the angle of incidence and the wavelength of ambient light fluctuate, the ambient light is divided into a large number of reflected-and-diffracted light beams and transmitted-and-diffracted light beams so that the fluctuations of intensity of each light beam are small and hence fluctuations of reflected ambient light that is an accumulation of a large number of such light beams are small. Note that the above effect is reduced when the lattice period is increased because the diffraction efficiency of the structure layer 105 falls and the proportion of light that is divided into diffracted light beams of higher orders becomes small. Thus, it is possible to provide an image display device showing only small fluctuations of contrast regardless of the surrounding environment as in the case of the image display device 100 of this embodiment.

The structure layer 105 of an image display device according to the present invention is by no means limited to the structure illustrated in FIGS. 1A and 1B, and the lattice period 13, the particle diameter 14 and/or the core diameter 15 may be different from those of this embodiment. A triangular lattice structure shows an excellent structural symmetry and a small angle dependency of light entering the micro-structure. Therefore, the angle dependency of the intensity of reflected ambient light from or that of display light of the image display device 100 can be reduced. Alternatively, the lattice period 13 and the particle diameter 14 may be different from each other and the particles 106 may be arranged in such a way that any adjacent ones do not contact each other. The intensity of each diffracted light beam produced from the structure layer 105 can be raised by appropriately selecting the particle diameter 14 and the core diameter 15 so as to diffract the light beams produced from the light-emitting layer and improve the effect of raising the brightness of display light. Alternatively, the particles 106 of the structure layer 105 may be arranged at random positions in a plane running in parallel with the front panel. Then, the locally differentiated characteristic values of angle dependency of the micro-structure are averaged among the pixels in the plane to consequently reduce the angle dependency of light entering the micro-structure and hence the angle dependency of the intensity of reflected ambient light from or that of display light of the image display device 100.

The front panel 101 of an image display device according to the present invention is formed by means of a material that is transparent relative to visible light, which may be plastic. Alternatively, the anode and the cathode of the excitation source 103 may be arranged respectively between the front panel 101 and the light-emitting layer 104 and on the rear surface of the light-emitting layer 104. The light-emitting layer 104 generates light as an electrical current is applied between the electrodes and electrons and holes are injected. Alternatively, the excitation source 103 may have one of its electrodes arranged on the substrate and its cells and its other electrode arranged on the front surface or the rear surface of the light-emitting layer 104. The cells contain gas in a sealed condition that gives rise to plasma and generates ultraviolet rays as an electric current is made to flow through them. With such an arrangement, as an electric current is made to flow through the gas contained in the cells, ultraviolet rays are generated and irradiated onto fluorescent particles to excite the fluorescent particles. The fluorescent particles may be dispersed in a medium that has a refractive index same as the fluorescent particles. With such an arrangement, scattering and reflection that take place due to the difference of refractive index, if any, at the boundaries between the fluorescent particles and the surrounding can be reduced. In this way, any scattering and reflection that may take place in the light-emitting layer 104 can effectively be suppressed. A medium having a refractive index other than the one described above for this embodiment may alternatively be used for the light-emitting layer 104.

### Embodiment 2

Now, Embodiment 2 of image display device according to the present invention that is different from Embodiment 1 will be described below by referring to FIG. 5. In FIG. 5 which is an xz cross sectional view of the image display device, 200 denotes the image display device. The image display device 200 of this embodiment includes a front panel 201, red pixels 202, green pixels 203 and blue pixels 204. The light-emitting section of each pixel is arranged at the rear surface of the front panel 201. The pixels are separated from each other by partition walls 212 formed by means of a light absorbing medium. FIG. 5 shows three pixels 202, 203 and 204 and the image display device 200 is formed by arranging a plurality of such pixels. The front panel 201 is formed by means of a medium that is transparent relative to visible light, which may typically be glass.

The light-emitting sections of the three pixels are formed respectively by means of light-emitting layers 205, 206 and 207, micro-structures 209, 210 and 211 and excitation sources 208. The micro-structures 209, 210 and 211 are arranged respectively on the front surfaces of the light-emitting layers 205, 206 and 207, while the excitation sources 203 are arranged respectively between the light-emitting layers 205, 206 and 207 and the front panel 201. The light-emitting layers 205, 206 and 207 of the pixels of different colors contain respective fluorescent materials that generate light of wavelengths of red, green and blue.

The micro-structure 209 contains particles 213, each of which includes a core 216 and a shell 219, arranged in a surrounding region 222. The core 216, the shell 219 and the surrounding region 222 are formed by means of respective mediums having refractive indexes that are different from each other. The medium of the shell 219 has a refractive index lower than the medium of the core 216 and higher than the medium of the front panel 201 or that of the surrounding region 222. Similarly, the micro-structures 210 and 211 respectively contains particles 214 and particles 215, each of the particles 214 including a core 217 and a shell 220, each of the particles 215 including a core 218 and a shell 221, arranged in surrounding regions 223 and 224. The core 217, the shell 220 and the surrounding region 223 are formed by means of respective mediums having refractive indexes that are different from each other. The core 218, the shell 221 and the surrounding region 224 are formed by means of respective mediums having refractive indexes that are different from each other. The mediums of the shells 220 and 221 respectively have refractive indexes lower than the mediums of the cores 217 and 218 and higher than the medium of the front panel 201 or the mediums of the surrounding regions 223 and 224.

Micro-structures 209, 210 and 211, which are different from each other in terms of structure or medium, are arranged respectively in the pixels 202, 203 and 204. Excitation sources 208 are layers including units for injecting electrons into the respective light-emitting layers 205, 206 and 207. For example, each of the excitation sources 208 may be formed by arranging an electron-emitting element (cathode) and an opposite electrode (anode) respectively on a substrate and on the surface of the light-emitting layer 102. With the above-described arrangement, as an electric field is applied between the electron-emitting element and the opposite electrode, electrons are emitted toward and fed to the light-emitting layers 205, 206 and 207 to make them emit light. The emitted light then passes through the respective micro-structures 209, 210 and 211 and the front panel 201 and are drawn to the outside to operate as display light.

For the image display device 200 of Embodiment 2, appropriate mediums are selected for the cores 216, 217 and 218, the shells 219, 220 and 221 and the surrounding regions 222, 223 and 224 of the pixels. The diameters and the positional arrangements of the macro-particles to be contained in the micro-structures 209, 210 and 211 are appropriately selected and the particle filling ratios of the mediums are also appropriately determined. Then, as a result, the effect of raising the brightness of display light and that of reducing the ambient light reflectance can be maximally exploited to provide an image display device capable of displaying images of high contrast if compared with an image display device where a same micro-structure is employed for all the pixels. Thus, micro-structures 209, 210 and 211 formed respectively by means of optimum mediums or structures selected from the view point of the mediums of the pixels 202, 203 and 204 and the wavelengths of light to be emitted from the pixels are used for the image display device 200 of this embodiment. Then, as a result, it is possible to provide an image display device that has a low ambient light reflectance and is capable of displaying images of high contrast. The particle diameter, the core diameter and the medium of each pixel are selected appropriately and by using them, micro-structures 209, 210 and 211 are prepared for the respective pixels by means of a process similar to the one described above for Embodiment 1. Then, it is possible to prepare micro-structures with ease for the pixels by means of respective structures or mediums that are different from each other.

Note that, in the image display device 200 of Embodiment 2, the micro-structures 209, 210 and 211 of the pixels may not necessarily be different from each other. In other words, it is sufficient that only the micro-structure of one of the pixels of red, green and blue is different from the remaining micro-structures of the other pixels. With such an arrangement, the effect of suppressing specular reflected light and diffused-and-reflected light and that of amplifying display light are improved further to provide an image display device capable of displaying images of high contrast. Alternatively, same and identical micro-structures may be employed for all the pixels. While the above-described effects may be reduced by using same micro-structures, the micro-structures can be prepared with ease because it is not necessary to employ different processes and process conditions for the different pixels. The micro-structures of this embodiment may not necessarily be triangular lattice structures as in the case of Embodiment 1. For example, structures in which particles are randomly arranged may alternatively be employed. Mediums of three or more different types having respective refractive indexes that are different from each other may be employed for the particles of the micro-structures. While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. This application claims the benefit of Japanese Patent Application No. 2009-286478, filed Dec. 17, 2009, which is hereby incorporated by reference herein in its entirety.

What is claimed is:

1. An image display device having a display surface constituted of a plurality of pixels, wherein:
each of the pixels having a light-emitting layer, a front panel arranged at the ambient light entering side relative to the light-emitting layer and a structure layer arranged between the light-emitting layer and the front panel;
the structure layer having a structure containing particles arranged in a surrounding region and showing a refractive index distribution in a plane parallel to the display surface;
each of the particles being constituted of a core and a shell forming an outer peripheral region relative to the core;
the core, the shell, and the front panel and/or the surrounding region being formed by media having different respective refractive indexes;
the refractive indexes satisfying the requirement of formula 1 shown below:
N_{core}>Nₛₕₑₗₗ>N_{low} (formula 1),
where
N_{core} represents the refractive index of the medium of the core;
Nₛₕₑₗₗ represents the refractive index of the medium of the shell; and
N_{low} represents the refractive index of the front panel or that of the surrounding region, whichever lower than the other.

2. The device according to claim 1, wherein,
when the light-emitting layer is formed by a medium that emits light within a wavelength zone between 350 nm and 800 nm and the refractive index distribution has a period Λ in the structure layer along a plane running in parallel with the display surface, the period Λ of the refractive index distribution satisfies the requirement of formula 2 shown below.
1.0 μm≦Λ≦3.0 μm (formula 2)

3. The device according to claim 1, wherein
the structure layer has a structure where particles are closely-packed and arranged in a plane running in parallel with the display surface.

4. The device according to claim 1, wherein
the particles have a core to shell ratio of not smaller than 0.3 and not greater than 0.95.

5. The device according to claim 1, wherein
the light-emitting layer is formed by a layer where fluorescent particles are dispersed in a medium having the same refractive index as the fluorescent particles.

6. The device according to claim 1, wherein:
pixels for emitting red light, those for emitting green light and those for emitting blue light are arranged and all the pixels are separated from each other by partition walls; and
the structure layer is provided for each pixel and has a structure different from other pixels.
